(19) United States
(12) Patent Application Publication
(10) Pub. No.: US 2014/0065766 A1
(43) Pub. Date: Mar. 6, 2014

(54) METHOD FOR FABRICATING WELL-ALIGNED ZINC OXIDE MICRORODS AND NANORODS AND APPLICATION THEREOF

(71) Applicant: National Taiwan University, Taipei (TW)

(72) Inventors: CHING-FUH LIN, Taipei (TW); Hua-Long SU, Taipei (TW)

(21) Appl. No.: 13/934,087

(22) Filed: Jul. 2, 2013

(30) Foreign Application Priority Data
Aug. 30, 2012 (TW) 101131537

(51) Int. Cl. H01L 21/02

(52) U.S. Cl. CPC H01L 21/0259
USPC 438/104

(57) ABSTRACT

The present invention relates to a method for fabricating well-aligned zinc oxide microrods and nanorods and application thereof and particularly relates to a method for fabricating well-aligned zinc oxide microrods and nanorods on a general substrate by hydrothermal method and application thereof.

### CROSS-REFERENCE TO RELATED APPLICATIONS

The entire contents of Taiwan Patent Application No. 101131537, filed on Aug. 30, 2012, from which this application claims priority, are incorporated herein by reference.

### BACKGROUND OF THE INVENTION

1. Field of the Invention

The present invention relates to a method for fabricating well-aligned zinc oxide (ZnO) microrods/nanorods and application thereof and particularly relates to a method for fabricating well-aligned zinc oxide (ZnO) microrods/nanorods by hydrothermal method and application thereof.

2. Description of Related Art

Currently, although lots of methods for forming well-oriented and large zinc oxide (ZnO) microrods/nanorods on common substrate have been developed, most of these methods are performed by Metal-Organic Chemical Vapor Deposition (MOCVD) or other growing process for forming zinc oxide (ZnO) microrods/nanorods. Most of these methods need to be performed under critical processing conditions, such as high temperature, low pressure, vacuum, etc. Therefore, the processes of these methods are more complicated and more difficult, and they need apparatuses which can provide these critical processing conditions. Most of these apparatuses are expensive and thereby the production cost of zinc oxide (ZnO) microrods/nanorods is too high to be decreased.

Furthermore, when the zinc oxide (ZnO) microrods/nanorods are fabricated by these methods, there are some wrinkles or grains forming on the surface of the seed layer of the zinc oxide microrods/nanorods. It results in uneven surface of the seed layer, and the uneven surface of the seed layer further causes generation of oblique and crookedness of the zinc oxide microrods/nanorods formed after the seed layer. Even it causes the zinc oxide microrods/nanorods to lean on each other. It makes a bad impact on the quality of these zinc oxide microrods/nanorods and even on the quality of the optical devices or photoelectric devices, which are produced by these zinc oxide microrods/nanorods in following process, because these zinc oxide microrods/nanorods are not well-aligned enough. Besides, following process of forming zinc oxide microrods/nanorods needs more critical process conditions because the seed layer is not even or planar enough. Therefore, the process conditions need to be controlled more accurately to ensure the zinc oxide microrods/nanorods to be straight without oblique and crookedness. Therefore, it results in the increasing difficulty of producing the zinc oxide microrods/nanorods.

Therefore, it has a need of a simple and cheap method for fabricating zinc oxide microrods/nanorods. The method can decrease the difficulty and thereby the zinc oxide microrods/nanorods can be fabricated under non-critical processing conditions and there is no need of the expensive apparatuses for fabricating zinc oxide microrods/nanorods. Therefore, the cost for fabricating zinc oxide microrods/nanorods on a common substrate can be decreased and the straightness of zinc oxide microrods/nanorods can be enhanced.

### SUMMARY OF THE INVENTION

In view of the foregoing, one object of the present invention is to provide a method for fabricating well-aligned zinc oxide (ZnO) microrods/nanorods instead of the conventional methods having a need of high cost, critical processing conditions, and expensive apparatuses, such as Metal-Organic Chemical Vapor Deposition (MOCVD) or other growing process for forming zinc oxide (ZnO) microrods/nanorods. Therefore, the difficulty and the cost for fabricating zinc oxide (ZnO) microrods/nanorods on a common substrate can be decreased, and the straightness of zinc oxide microrods/nanorods can be enhanced efficiently. Furthermore, optical devices or photoelectronic devices having high quality can be fabricated by using the zinc oxide microrods/nanorods, which are fabricated this method of present invention, as an epitaxial center.

According to the objects above, a method for fabricating well-aligned zinc oxide (ZnO) microrods/nanorods is disclosed herein. The method comprises following steps: (1) providing a substrate; (2) forming a zinc oxide thin film on the substrate; (3) baking the zinc oxide thin film with temperature control; (4) forming a suppressing layer on the zinc oxide thin film, and then, annealing the zinc oxide thin film and the substrate with high temperature; (5) removing the suppressing layer after annealing; and (6) forming zinc oxide microrods/nanorods on the sine oxide thin film by hydrothermal method.

Therefore, the present invention provides a method for fabricating well-aligned zinc oxide (ZnO) microrods/nanorods and this method having advantages of less processing condition requirements, less difficulty and low cost is provided in this invention instead of the conventional method having much processing condition requirements, much difficulty and high cost, to form straighter zinc oxide (ZnO) microrods/nanorods on a common substrate. The zinc oxide (ZnO) microrods/nanorods, which are fabricated this method of present invention, can be used as an epitaxial center to produce high quality optical devices or photoelectronic devices.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A to FIG. 1G are a series of cross-section drawings illustrating a method for fabricating well-aligned zinc oxide microrods/nanorods in accordance with an embodiment of the present invention.

FIG. 2A and FIG. 2B are SEM images in plane view of a zinc oxide thin film without baking and a zinc oxide thin film after baking.

FIG. 3A and FIG. 3B are SEM images in plane view of a zinc oxide thin film after annealing and a zinc oxide thin film after baking and anneal.

FIG. 4A and FIG. 4B are a SEM image in plane view of zinc oxide microrods/nanorods and a SEM image in cross-section view of zinc oxide microrods/nanorods in accordance with an embodiment of the present invention.

### DETAILED DESCRIPTION OF THE PREFERRED EMBODIMENT

The detailed description of the present invention will be discussed in the following embodiments, which are not intended to limit the scope of the present invention, and can be adapted for other applications. While drawings are illustrated in detail, it is appreciated that the quantity of the disclosed components may be greater or less than that disclosed, except where expressly restricting the amount of the components.

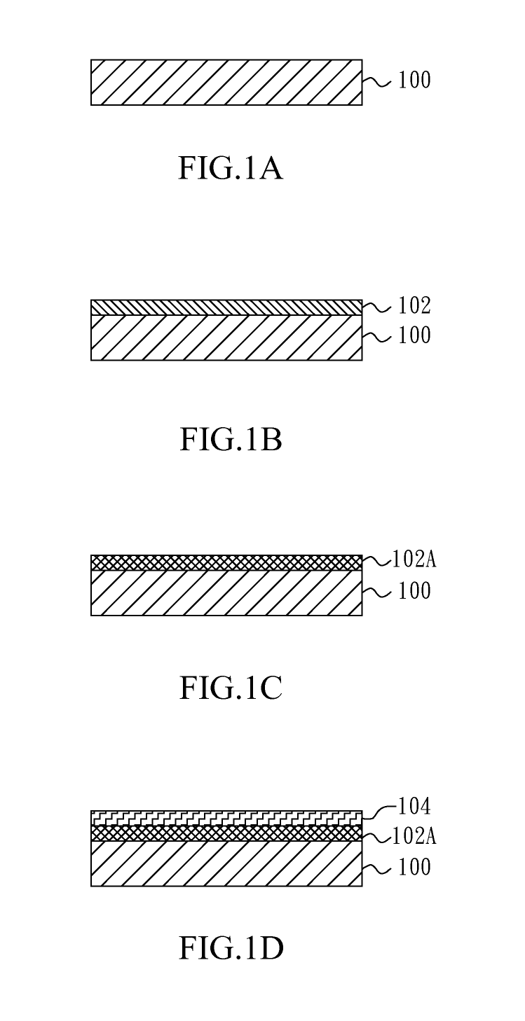

FIG. 1A to FIG. 1G show a method for fabricating well-aligned zinc oxide (ZnO) microrods/nanorods in accordance with an embodiment of the present invention, and they are a series of cross-section drawings illustrating the process of this method and different steps of this method. Referring to FIG. 1A, first, a substrate 100 is provided wherein the substrate 100 is a metal substrate, a silicon substrate, a quartz substrate, a glass substrate, a sapphire substrate, or a flexible plastic substrate. Then, a cleaning step is performed. In this cleaning step, the substrate 100 is washed by acetone or methanol firstly, and then, the substrate 100 is washed by deionized water and the substrate 100 is dried by blowing.

Next, referring to FIG. 1B, a zinc oxide thin film 102 is formed on the substrate 100 to be a seed layer for fabricating zinc oxide microrods/nanorods. The zinc oxide thin film 102 is formed on the substrate 100 by sol-gel method wherein a mixed solution composed of monoethanolamine, zinc acetate, and ethylene glycol monoethyl ether or a mixed solution which can precipitate zinc oxide by chemical reactions is used as a chemical solution used in the sol-gel method. The chemical solution is coated on the substrate 100 by spin coating or other coating methods to form the zinc oxide thin film 102.

Then, referring to FIG. 1C, the zinc oxide thin film 102 is baked with temperature control (or a temperature controlling process) for flattening the surface of the zinc oxide thin film 102. Therefore, a zinc oxide thin film 102A, which has a planar surface without wrinkles and grains, is formed on the substrate 100. In this baking step, the speed of temperature variation of the temperature control (or temperature controlling process) is at a range of 5° C. per minute to 20° C. per minute and the temperature control process is performed at 100° C. to 300° C. In this step, the zinc oxide thin film 102 is baked with temperature control from 100° C. to 300° C. for 10 minutes to 1 hour. In a preferred embodiment of the present invention, the zinc oxide thin film 102 is baked with temperature control at 150° C. to 300° C. for 30 minutes. Generation of wrinkles and grams on the zinc oxide thin film 102 results from combinations of zinc and hydroxyl groups (—OH) of organic molecules in the zinc oxide thin film 102. Therefore, the baking step is available to remove the organic molecules in the zinc oxide thin film 102 for directly combining zinc with oxygen atoms to form a uniform zinc oxide thin film. If means that the uneven zinc oxide thin film 102 is converted into the uniform zinc oxide thin film 102A by baking with temperature control.

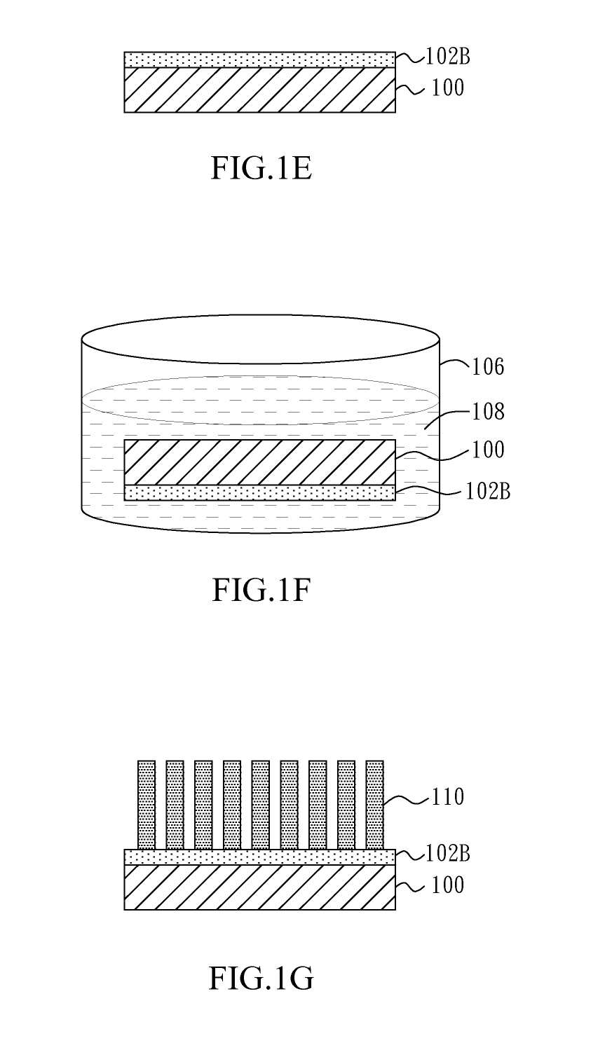

Please refer to actual experiments, as FIG. 2A shows; there are many wrinkles and grains on the surface of the zinc oxide thin film which is not baked by temperature control. These wrinkles and grains result in the uneven surface of the zinc oxide thin film, and they will influence the straightness and quality of the zinc oxide microrods/nanorods formed in following process (or steps). As FIG. 2B shows, there is no wrinkle and grain on the surface of the zinc oxide thin film which is baked by temperature control. Therefore, the surface of the zinc oxide thin film is even, and the straightness and quality of the zinc oxide microrods/nanorods formed in following process (or steps) will not be influenced by wrinkle, grain, and uneven surface of the zinc oxide thin film. By this step, straightness of the zinc oxide microrods/nanorods formed in following process (or steps) can be enhanced and the zinc oxide microrods/nanorods formed in following process (or steps) can be grown under non-critical condition, such as room temperature and normal atmosphere.

After, referring to FIG. 1D, a suppressing layer 104 is formed on the baked zinc oxide thin film 102A. The suppressing layer 104 is a metal, for example gold (Au), silver (Ag), nickel (Ni), chromium (Cr), etc., or an oxide, it can be formed or deposited on the baked zinc oxide thin film 102A by electroplating, sputtering, depositing, or other similar methods. Then, the baked zinc oxide thin film 102A and the substrate 100 are annealed with higher temperature to form a (annealed) zinc oxide thin film 102B which is annealed with high temperature.

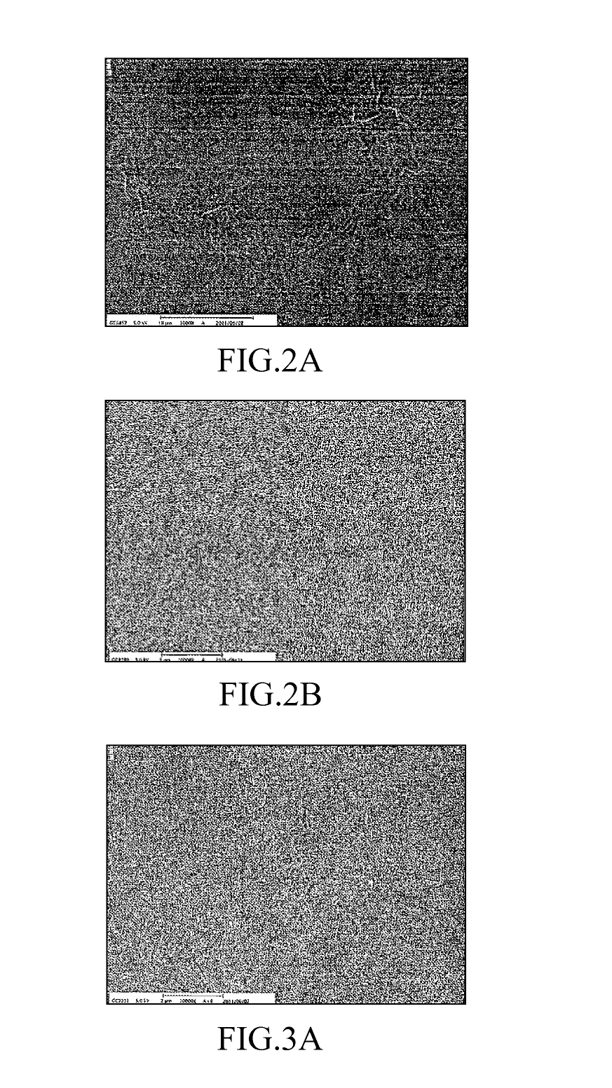

Please refer to actual experiments, as FIG. 3A shows, although the surface of the zinc oxide thin film, which is not baked by temperature control but is annealed by high temperature, becomes flatter after annealing, the surface of the annealed zinc oxide thin film is not flat enough. It is because there are many wrinkles and grains on the zinc oxide thin film before annealing. Therefore, even though the zinc oxide thin film is annealed with high temperature, the surface of the annealed zinc oxide thin film is not flat enough to avoid making a bad impact on the straightness and quality of the zinc oxide microrods/nanorods formed in following process (or steps). As FIG. 3B shows, the surface of the zinc oxide thin film, which is baked with temperature control and annealed in high temperature, are still flat after annealing because there is no wrinkle and grain on the surface of the zinc oxide thin film after baking. Even though the zinc oxide thin film is annealed with high temperature, the surface of the annealed zinc oxide thin film which is baked by temperature control before annealing (as FIG. 3B shows) is still much flatter than the surface of the annealed zinc oxide thin film which is not baked with temperature control (as FIG. 3A shows). Therefore, the straightness and quality of the zinc oxide microrods/nanorods formed in following process (or steps) will not be influenced by wrinkle, grain, and uneven surface of the (annealed) zinc oxide thin film. By this step, straightness of the zinc oxide microrods/nanorods formed in following process (or steps) can be enhanced and the zinc oxide microrods/nanorods formed in following process (or steps) can be grown under non-critical condition, such as room temperature and normal atmosphere.

Then, referring to FIG. 1E, the suppressing layer 104 is removed from the annealed zinc oxide thin film 102B after annealing. In this step, the suppressing layer 104 is removed by etching, and a mixed aqueous solution of iodine/potassium iodide, hydrofluoric acid (HF), sulfuric acid, nitric acid, or mixed solution of these acids is used as an etching solution to remove the suppressing layer 104.

After, referring to FIG. 1F, the substrate 100 (including the annealed zinc oxide thin film 102B thereon) is put or dipped into a container 108 having a chemical solution 108 and the annealed zinc oxide thin film 102B is used as an epitaxial center or a seed layer for forming or growing zinc oxide microrods/nanorods 110 on the annealed zinc oxide thin film 102B by hydrothermal method. The chemical solution 108a is a zinc nitrate/hexamethylenetetramine aqueous solution or a mixed aqueous solution, in which zinc oxide is precipitated through chemical reaction. The concentration of the chemical solution 108 is 50 mM to 220 mM but not limited to this. Various chemical solutions and various concentration of the chemical solution 108 can be applied in the hydrothermal method according to requirement of this process, such as the desired deposition rate. The zinc oxide microrods/nanorods 110 are formed or grown at 60° C. to 150° C., and the preferred temperature of this step is at 65° C. to 90° C. The process time of this step is 1 hour to 100 hours, such as 1 hour to 24 hours, but not limited to this. Various process times can be applied in the hydrothermal method according to different processing conditions of this step, such as the process temperature, the composition and concentration of the chemical solution 108. Besides, although the substrate 100 (including the annealed zinc oxide thin film 102B thereon) is put or dipped into a container 106 having the chemical solution 108 upside down in the step illustrated in FIG. 1F, the substrate 100 (including the annealed zinc oxide thin film 102B thereon) can be put or dipped into a container 106 having the chemical solution 108 with the annealed zinc oxide thin film 102B facing upward in another embodiment of this invention.

Finally, referring to FIG. 1G, after reacting a period of time, there are many zinc oxide microrods/nanorods 110 formed or grown on the annealed zinc oxide thin film 102B wherein the zinc oxide microrods/nanorods 110 have a predetermined meter and a predetermined length. Then, the substrate 100 is taken out or picked up from the chemical solution 108 and production process of the zinc oxide microrods/nanorods 110 is completed. The diameters of the zinc oxide microrods/nanorods 110 are 300 nm to 2 μm, and the lengths of the zinc oxide microrods/nanorods 110 are 1 μm to 10 μm. However, both length and diameter are not limited to this, and both can be determined according to different requirements and parameters in the hydrothermal process.

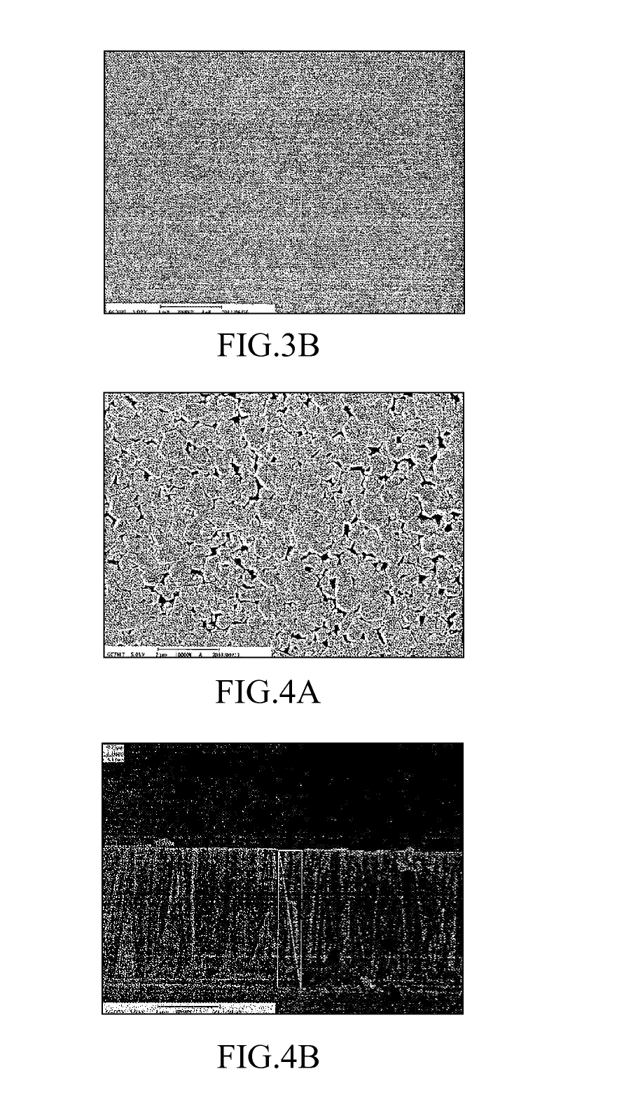

Please refer to actual experiments, as FIG. 4A and FIG. 4B show, the zinc oxide microrods/nanorods fabricated by the method of this invention have both good straightness and well-alignment. In the present invention, because the zinc oxide thin film, which is used as an epitaxial center or a seed layer, is baked to be flat, there is no wrinkle and grain existing on the zinc oxide thin film and the growing of the zinc oxide microrods/nanorods in following step is not influenced by the wrinkles and the grains. On the contrary, by the methods of this invention, a flat zinc oxide thin film is provided to be an epitaxial center or a seed layer and the zinc oxide microrods/nanorods can be formed or grown on the even zinc oxide thin film straightly. Therefore, the zinc oxide microrods/nanorods which are straighter than the zinc oxide microrods/nanorods fabricated by the conventional methods and the zinc oxide microrods/nanorods formed in following process (or steps) can be grown under non-critical condition, such as room temperature and normal atmosphere.

Besides, in the method for fabricating well-aligned zinc oxide (ZnO) microrods/nanorods disclosed in this invention, the zinc oxide microrods/nanorods are fabricated on a common substrate by the chemical solution method. Therefore, in this method, there is no need to fabricate the zinc oxide microrods/nanorods under critical processing conditions, such as high temperature, high vacuum, and there is no need of the expensive apparatuses for providing these critical processing conditions. Accordingly, by this method disclosed in this invention, the process for fabricating zinc oxide microrods/nanorods can be simplified, and the difficulty and the cost for fabricating zinc oxide microrods/nanorods can be decreased. Furthermore, by this method, the fabricating zinc oxide microrods/nanorods can be fabricated on large area without any damage of the substrate.

Moreover, the zinc oxide microrods/nanorods, which is fabricated by the method for fabricating well-aligned zinc oxide (ZnO) microrods/nanorods disclosed in this invention (the method illustrated in FIG. 1A-FIG. 1G), can be applied to form optical devices or photoelectronic devices. After the zinc oxide microrods/nanorods is fabricated by the steps illustrated in FIG. 1A-FIG. 1G, nitride based epitaxial layers can be formed on the zinc oxide microrods/nanorods via device manufacturing process in order to fabricate photoelectronic semiconductor devices. The device manufacturing process could be performed by atomic layer deposition, electrochemical deposition, pulsed laser deposition, or metal-organic chemical vapor deposition. The zinc oxide microrods/nanorods, which is fabricated by the method for well-aligned zinc oxide (ZnO) microrods/nanorods disclosed in this invention (the method illustrated in FIG. 1A-FIG. 1G), is straighter and there is less oblique and crookedness of the zinc oxide microrods/nanorods. Therefore, it is helpful to form high-quality nitride based semiconductor epitaxial layers on the zinc oxide microrods/nanorods and high-quality optical devices or photoelectric devices can be formed by this method.

Accordingly, a method for fabricating well-aligned zinc oxide (ZnO) microrods/nanorods is provided in this invention, in which the liquid chemical method (or the hydrothermal method) having advantages of simple process steps, less process conditions (or requirements) and low process (or producing) cost is utilized instead of the conventional methods having disadvantages of complicated process steps, much process conditions (or requirements) and critical process (or producing) cost, such as electrochemical deposition, pulsed laser deposition, or metal-organic chemical vapor deposition, to produce the zinc oxide microrods/nanorods on a common substrate. By this way, the difficulty and cost of production of the zinc oxide microrods/nanorods can be reduced or decreased. Thus, the process of production of the zinc oxide microrods/nanorods can be simplified and the requirement and the cost of production of the zinc oxide microrods/nanorods can be decreased. Furthermore, in the present invention, the zinc oxide thin film is baked by temperature to flatten the zinc oxide thin film and thereby an even epitaxial center or seed layer without wrinkles and grains is provided. It is helpful to enhance the straightness of the zinc oxide microrods/nanorods and the zinc oxide microrods/nanorods can be formed or grown under non-critical condition. Furthermore, a method for fabricating high-quality optical devices or photoelectric devices, which has advantages of simple process steps, less process conditions (or requirements) and low process (or producing) cost, by applying the method of this invention for fabricating well-aligned zinc oxide microrods/nanorods is provided in this invention.

Although specific embodiments have been illustrated and described, it will be appreciated by those skilled in the art that various modifications may be made without departing from the scope of the present invention, which is intended to be limited solely by the appended claims.

What is claimed is:

1. A method for fabricating well-aligned zinc oxide microrods/nanorods, comprising:
(1) providing a substrate;
(2) forming a zinc oxide thin film on said substrate;
(3) baking said zinc oxide thin film with temperature control;
(4) forming a suppressing layer on said zinc oxide thin film, and then, annealing said zinc oxide thin film and said substrate with high temperature;
(5) removing said suppressing layer after annealing; and
(6) forming zinc oxide microrods/nanorods on said zinc oxide thin film by hydrothermal method.

2. The method of claim 1, wherein said substrate is a metal substrate, a silicon substrate, a quartz substrate, a glass substrate, a sapphire substrate, or a flexible plastic substrate.

3. The method of claim 1, wherein in said step (2), said zinc oxide thin film is formed by sol-gel method.

4. The method of claim 3, wherein a chemical solution used in said sol-gel method is a mixed solution composed of monoethanolamine, zinc acetate, and ethylene glycol monoethyl ether, or a mixed solution which can precipitate zinc oxide by chemical reactions.

5. The method of claim 4, wherein said chemical solution is coated on said substrate by spin coating.

6. The method of claim 1, wherein said step (3) is performed to flatten surfaces of said zinc oxide thin film for preventing generation of wrinkles or grains on said zinc oxide thin film.

7. The method of claim 1, wherein said temperature control in said step (3) is performed at 100° C. to 300° C.

8. The method of claim 1, wherein speed of temperature variation of said temperature control in said step (3) is at a range of 5° C. per minute to 20° C. per minute.

9. The method of claim 1, wherein process time of said step (3) is 10 minutes to 1 hour.

10. The method of claim 1, wherein said suppressing layer is a metal or an oxide.

11. The method of claim 10, wherein said metal is gold (Au), silver (Ag), nickel (Ni), or chromium (Cr).

12. The method of claim 1, wherein in said step (5), said suppressing layer is removed by etching.

13. The method of claim 12, wherein in said step (5), a mixed aqueous solution of iodine/potassium iodide, hydrofluoric acid (HF), sulfuric acid, nitric acid, or mixed solution of said acids is used as an etching solution to remove said suppressing layer.

14. The method of claim 1, wherein in said step (6), said zinc oxide film through baking and anneal is used as an epitaxial center or seed-layer for growing said well-aligned zinc oxide microrods/nanorods.

15. The method of claim 1, wherein diameters of said well-aligned zinc oxide microrods/nanorods are 300 nm to 2 μm.

16. The method of claim 1, wherein lengths of said well-aligned zinc oxide microrods/nanorods are 1 μm to 10 μm.

17. The method of claim 1, wherein in said step (6), a zinc nitrate/hexamethylenetetramine aqueous solution or a mixed aqueous solution, in which zinc oxide is precipitated through chemical reaction, is used as a chemical solution of hydrothermal method for growing said well-aligned zinc oxide microrods/nanorods on said zinc oxide thin film by said hydrothermal method.

18. The method of claim 17, wherein concentration of said chemical solution is 50 mM to 220 mM.

19. The method of claim 1, wherein said step (6) is performed at 60° C. to 150° C.

20. The method of claim 1, wherein process time of said step (6) is 1 hour to 100 hours.

21. The method of claim 1, wherein further comprises a device manufacturing process for forming nitride based semiconductor crystal or epitaxial layers on said well-aligned zinc oxide microrods/nanorods to produce optical devices or photoelectric devices.

22. The method of claim 21, wherein said device manufacturing process is performed by atomic layer deposition, electrochemical deposition, pulsed laser deposition, or metalorganic chemical vapor deposition to form said nitride based semiconductor crystal or epitaxy on said well-aligned zinc oxide microrods/nanorods.
